(19) United States
(12) Patent Application Publication
(10) Pub. No.: US 2026/0059839 A1
(43) Pub. Date: Feb. 26, 2026

(54) SEMICONDUCTOR DEVICE MANUFACTURED USING GATE-LEANING PREVENTION STRUCTURE

(71) Applicant: SAMSUNG ELECTRONICS CO., LTD., Suwon-si (KR)

(72) Inventors: Yeojin Lee, Cohoes, NY (US); Kang-ill Seo, Springfield, VA (US)

(73) Assignee: SAMSUNG ELECTRONICS CO., LTD., Suwon-si (KR)

(21) Appl. No.: 19/174,419

(22) Filed: Apr. 9, 2025

Related U.S. Application Data
(60) Provisional application No. 63/685,041, filed on Aug. 20, 2024.
(60) Provisional application No. 63/685,054, filed on Aug. 20, 2024.

(51) Int. Cl. H10D 64/27; H10D 64/01; H10D 84/83

(52) U.S. Cl. CPC H10D 64/519; H10D 64/017; H10D 64/027; H10D 84/83

(57) ABSTRACT

Provided is a semiconductor device which includes: a 1^{st} gate structure; a 2^{nd} gate structure adjacent to the 1^{st} gate structure in the 1^{st} direction; and a gate support structure between the 1^{st} gate structure and the 2^{nd} gate structure, the gate support structure connecting the 1^{st} gate structure and the 2^{nd} gate structure.

### CROSS-REFERENCE TO RELATED APPLICATION

This application is based on and claims priority from U.S. Provisional Application Nos. 63/685,041 and 63/685,054 filed on Aug. 20, 2024 in the U.S. Patent and Trademark Office, the disclosures of which are incorporated herein in its entirety by reference.

### BACKGROUND

### 1. Field

Apparatuses and methods consistent with the disclosure relate to a semiconductor device which is formed based on a gate-leaning prevention structure during a manufacturing process of the semiconductor device.

### 2. Description of Related Art

In response to increased demand for a semiconductor device having a high device density, the size of a semiconductor device has been reduced in terms of at least a cell height of a semiconductor cell for the semiconductor device, a gate pitch, referred to as contact poly pitch (CPP), between gate structures formed in the semiconductor cell, and an aspect ratio of structural elements such as a gate structure, a contact structure, etc. of the semiconductor device. However, with the CPP of gate structures decreasing and the aspect ratio of the gate structures increasing, the gate structures may not be formed properly when a gate leaning phenomenon occurs in a manufacturing process of a semiconductor device including the gate structures. The gate leaning phenomenon refers to a structural defect in which one or more gate structures lean toward one or more adjacent gate structures, reducing inter-gate spacing and compromising electrical isolation therebetween. The gate leaning may even result in collapse of the gate structures in the semiconductor device. This gate leaning phenomenon may occur during operations of patterning dummy gate structures, forming source/drain patterns, replacing the dummy gate structures with gate structures, etc. that are performed at a high temperature with a nanometer-scale process margin.

FIG. 1 illustrates a plan view of a semiconductor device in which a plurality of gate structures are properly formed across a plurality of active patterns, and FIG. 2 illustrates a plan view of a semiconductor device in which gate leaning has occurred between adjacent gate structures.

Referring to FIG. 1, a semiconductor device 10 may include a plurality of active patterns 110 formed on a substrate 101 and a plurality of gate structures 160 formed across the active patterns 110. The active patterns 110 are extended in a 1^{st} direction D1 and arranged in a 2^{nd} direction D2 intersecting the 1^{st} direction D1. The 1^{st} and 2^{nd} directions D1 and D2 both may be referred to as horizontal directions. The active patterns 110 may be epitaxially grown from the substrate 101 in a 3^{rd} direction D3, which is a vertical direction intersecting the 1^{st} and 2^{nd} directions D1 and D2, which are horizontal directions. The gate structures 160 may extend in the 2^{nd} direction D2 and are arranged in the 1^{st} direction D1 with a predetermined CPP.

In the semiconductor device 10, because any two adjacent gate structures 160 are properly spaced by the CPP, transistor structures that include the gate structures 160 and active elements (channel structures formed from the active patterns 110 and source/drain patterns formed from the active patterns 110) can perform intended logic functions.

However, in a semiconductor device 20 of FIG. 2 including a substrate 201, a plurality of active patterns 210 and a plurality of gate structures 260 respectively corresponding to the substrate 101, the active pattern 110 and the gate structures 160 of FIG. 1, the gate structures 260 may not maintain the CPP between certain adjacent gate structures because of gate leaning that occurs therebetween. For example, one gate structure 260 might be formed too close to an adjacent gate structure, which generates a short-circuit risk and prevents formation of channel structures surrounded by the two gate structures 260 and source/drain patterns between the two gate structures 260, thereby failing to form a transistor structure that can perform intended logic functions.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

The disclosure provides a semiconductor device manufactured using a gate-leaning prevention structure formed between two adjacent gate structures. During a process of manufacturing the semiconductor device, a dummy support structures may be formed between two adjacent dummy gate structures to prevent gate leaning therebetween, and further, a gate support structure may be formed between two adjacent gate structures to prevent gate leaning therebetween. The gate support structures may be electively removed after formation of the gate structures.

According to an aspect of the disclosure, there is provided a semiconductor device which may include: a 1^{st} gate structure; a 2^{nd} gate structure adjacent to the 1^{st} gate structure in the 1^{st} direction; and a gate support structure between the 1^{st} gate structure and the 2^{nd} gate structure, the gate support structure connecting the 1^{st} gate structure and the 2^{nd} gate structure.

According to an aspect of the disclosure, there is provided a semiconductor device which may include: a source/drain pattern and a channel structure connected in a 1^{st} direction; and a 1^{st} gate structure extended in a 2^{nd} direction across the channel structure, the 2^{nd} direction intersecting the 1^{st} direction, wherein a side surface of the 1^{st} gate structure comprises a 1^{st} recessed portion.

According to an aspect of the disclosure, there is provided a method of manufacturing a semiconductor device, which may include: forming a 1^{st} gate structure and a 2^{nd} gate structure adjacent to the 1^{st} gate structure, the 1^{st} gate structure and the 2^{nd} gate structure extended in a 2^{nd} direction intersecting a 1^{st} direction; and forming a gate support structure between the 1^{st} gate structure and the 2^{nd} gate structure to connect the 1^{st} gate structure and the 2^{nd} gate structure.

According to an aspect of the disclosure, there is provided a method of manufacturing a semiconductor device, which may include: forming a plurality of dummy gate structures arranged in a 1^{st} direction and extending in a 2^{nd} direction intersecting the 1^{st} direction; forming a 1^{st} dummy support structure connecting a 1^{st} dummy gate structure and a 2^{nd} dummy gate structure adjacent to the 1^{st} dummy gate structure, among the plurality of dummy gate structures; and forming a plurality of gate structures and a 1^{st} gate support structure replacing the plurality of dummy gate structures and the 1^{st} dummy support structure, wherein the 1^{st} gate support structure connects a 1^{st} gate structure and a 2^{nd} gate structure, among the plurality of gate structures, replacing the 1^{st} dummy gate structure and the 2^{nd} dummy gate structure.

According to an aspect of the disclosure, there is provided a method of manufacturing a semiconductor device, which may include: forming an initial dummy gate structure on a substrate with an active pattern thereon; forming a 1^{st} hard mask layer on the initial dummy gate structure; forming a mask-pattern support structure extending in a 1^{st} direction on the 1^{st} hard mask pattern; forming a 2^{nd} hard mask layer on the 1^{st} hard mask pattern with the mask-pattern support structure thereon; patterning the 1^{st} hard mask layer and the 2^{nd} hard mask layer to form a hard mask pattern comprising a plurality of patterns arranged in the 1^{st} direction and extending in a 2^{nd} direction intersecting the 1^{st} direction; patterning the initial dummy gate structure based on the hard mask pattern to form a plurality of dummy gate structures arranged in the 1^{st} direction and extending in the 2^{nd} direction; forming a plurality of gate structures replacing the plurality of dummy gate structures, and removing the mask-pattern support structure.

### BRIEF DESCRIPTION OF DRAWINGS

Example embodiments of the disclosure will be more clearly understood from the following detailed description taken in conjunction with the accompanying drawings.

FIG. 1 illustrates a plan view of a semiconductor device in which a plurality of gate structures are properly formed across a plurality of active patterns.

FIG. 2 illustrates a plan view of a semiconductor device in which gate leaning has occurred between gate structures.

FIGS. 3A-3H illustrate intermediate semiconductor devices obtained after respective steps of manufacturing a semiconductor device using a randomly-positioned dummy gate support structure as a gate-leaning prevention structure, according to one or more embodiments.

FIGS. 4A-4H illustrate intermediate semiconductor devices obtained after respective steps of manufacturing a semiconductor device using a uniformly-positioned dummy gate support structure as a gate-leaning prevention structure, according to one or more embodiments.

FIGS. 5A and 5B are a flowchart of manufacturing a semiconductor device using a dummy gate support structure as a gate-leaning prevention structure, according to one or more embodiments.

FIGS. 6A-6L illustrate intermediate semiconductor devices obtained after respective steps of manufacturing a semiconductor device using a mask-pattern support structure as a gate-leaning prevention structure, according to one or more embodiments.

FIGS. 7A and 7B are a flowchart of manufacturing a semiconductor device using a mask-pattern support structure as a gate-leaning prevention structure, according to one or more embodiments.

FIG. 8 is a schematic block diagram illustrating an electronic device including one or more semiconductor devices formed using a gate-leaning prevention structure, according to one or more embodiments.

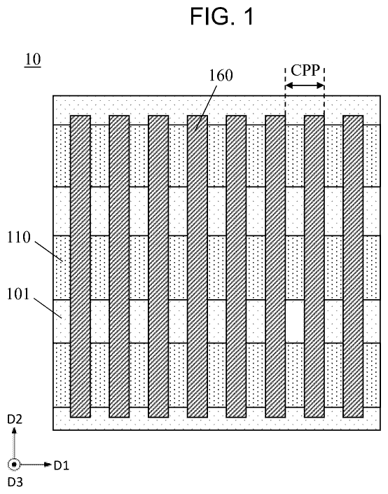

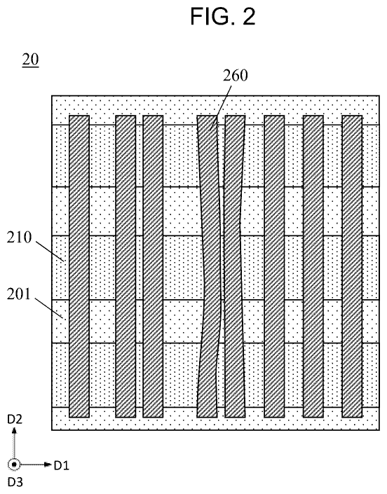

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd},” “4^{th} ,” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

In the descriptions herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same”parameters.

It will be understood that, when the term “contact” is used to describe two metal elements, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contract structure is described as being formed on or contact a surface of a source/drain pattern, a silicide layer such as cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to plan views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

It will be also understood that, although a certain structure (e.g., a gate structure, a gate support structure, etc.) is described as being formed or manufactured through a particular method or process or using a particular material in the embodiments described herein, that particular method or process and material do not limit the disclosure. Thus, a different method or process and a different material may also be used to form or manufacture the certain structure unless such method or process and material are specifically described as excluding another method or process and another material to form or manufacture the certain structure to serve the same or similar purposes.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” pertains to electrical insulation or separation between structures, layers, components or regions in a corresponding device or structure.

In order to address gate leaning occurring between adjacent gate structures in a semiconductor device as described in the background section, the following embodiments are provided.

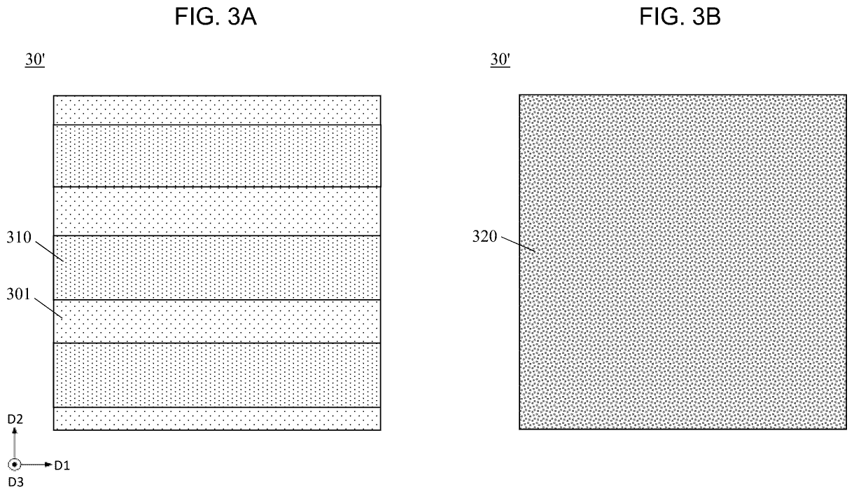

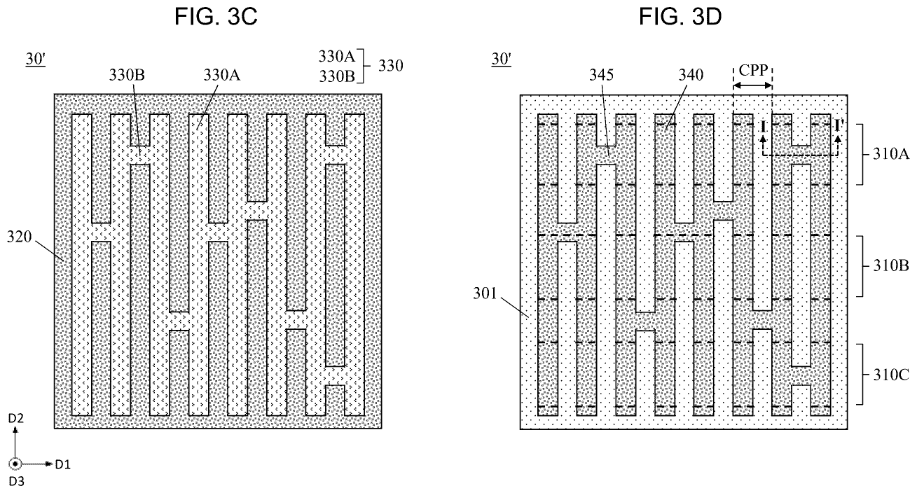

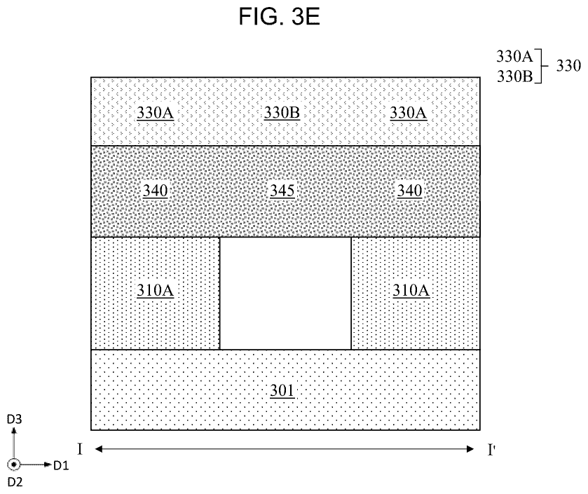

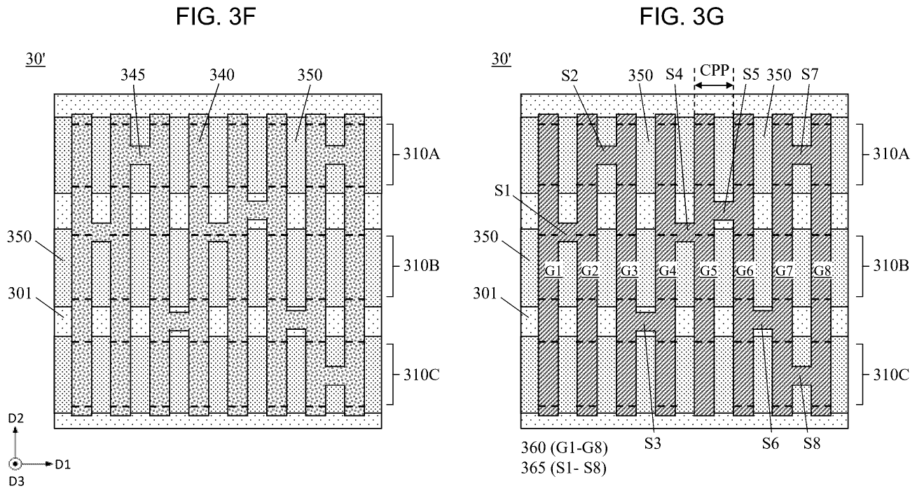

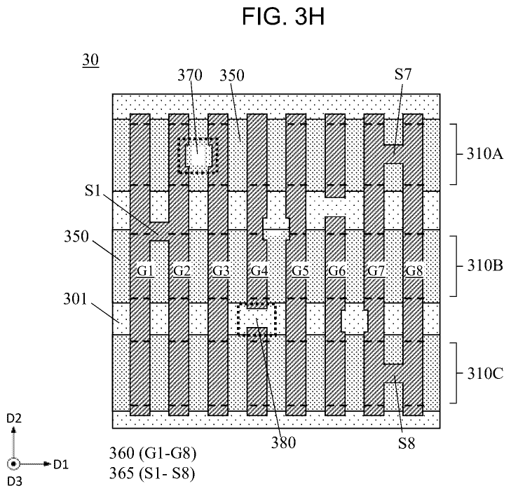

FIGS. 3A-3H illustrate intermediate semiconductor devices obtained after respective steps of manufacturing a semiconductor device using a randomly-positioned dummy gate support structure as a gate-leaning prevention structure, according to one or more embodiments.

Referring to FIG. 3A, an intermediate semiconductor device 30′ including a substrate 301 and a plurality of active patterns 310 formed thereon may be provided.

The active patterns 310 may be formed to extend in the 1^{st} direction D1 and be arranged in the 2^{nd} direction D2. The active patterns 310 may be epitaxially grown from the substrate in the 3^{rd} direction D3, and thus, may be formed of the same material, e.g., silicon (Si), forming the substrate 301. The active patterns 310 may be protruded from the substrate 301 in the 3^{rd} direction D3, and thus, a top surface of each of the active patterns 310 may be at a level higher than a top surface of the substrate 301 in the 3^{rd} direction D3. The active patterns 310 may be selectively doped with impurities to achieve desired electrical characteristics. The active patterns 310 may form channel structures of transistors in a semiconductor device to be completed from the intermediate semiconductor device 30′ in a later step (FIG. 3H).

Referring to FIG. 3B, an initial dummy gate structure 320 may be formed on the intermediate semiconductor device 30′ provided in the previous step (FIG. 3A).

The initial dummy gate structure 320 may be formed on a top surface of the intermediate semiconductor device 30′ shown in FIG. 3A through, for example, chemical vapor deposition (CVD), plasma enhanced chemical vapor deposition (PECVD), physical vapor deposition (PVD), or a combination thereof, not being limited thereto. Thus, top surfaces of the active patterns 310 and a top surface of the substrate 301 exposed at sides of the active patterns 310 in the 2^{nd} direction D2 may be at least partially covered by and contact the initial dummy gate structure 320 in the 3^{rd} direction D3. The material forming the initial dummy gate structure 320 may be polycrystalline silicon (p-Si) or amorphous silicon (a-Si).

The initial dummy gate structure 320 is to be patterned in a later subsequent step (FIG. 3D) to form a plurality of dummy gate structures which are respective placeholders for a plurality of gate structures and serve to define channel structures.

Referring to FIG. 3C, a hard mask pattern 330 may be formed on a top surface of the initial dummy gate structure 320 to pattern a plurality of dummy gate structures in a next step (FIG. 3D).

The hard mask pattern 330 may be formed through, for example, applying photolithography and dry etching to at least one hard mask layer formed on the top surface of the initial dummy gate structure 320. The hard mask layer patterned as the hard mask pattern 330 may be formed of, for example, silicon nitride (e.g., SiN and Si₃N₄) or silicon oxide (e.g., SiO₂), not being limited thereto. In a case in which the at least one hard mask layer is two or more hard mask layers stacked in the 3^{rd} direction D3 to provide a structural strength for a masking structure, a silicon nitride layer and a silicon oxide layer may be stacked in an alternating manner. In this case the hard mask pattern 330 may also be a multi-layer hard mask pattern including a silicon nitride pattern and a silicon oxide pattern alternatingly stacked in the 3^{rd} direction D3.

Here, the hard mask pattern 330 may be formed to include a plurality of 1^{st} portions 330A extended in the 2^{nd} direction D2 and a plurality of 2^{nd} portions 330B each connecting two adjacent 1^{st} portions 330A. For example, the two adjacent 1^{st} portions 330A and the 2^{nd} portion 330B therebetween may form an “H′ shape.

The 1^{st} portions 330A may be formed to pattern a plurality of dummy gate structures and the 2^{nd} portions 330B may be formed to pattern a plurality of dummy support structures disposed between two adjacent dummy gate structures, in a next step (FIG. 3D). The dummy support structures are to prevent a gate-leaning phenomenon that may occur during a process of patterning the dummy gate structures and subsequent processes until the dummy gate structures are replaced by gate structures. The 2^{nd} portions 330B may be randomly positioned between the first portions 330A, however, considering design of a circuit structure to be implemented in the semiconductor device completed from the intermediate semiconductor device 30′. This will be further described later.

FIG. 3C shows that the hard mask pattern 330 includes eight 1^{st} portions 330A and eight 2^{nd} portions 330B with at least one 2^{nd} portion 330B formed between two adjacent 1^{st} portions 330A. However, the disclosure is not limited thereto. According to one or more other embodiments, more or less than eight 1^{st} portions 330A, or more or less than eight 2^{nd} portions 330B may form the hard mask pattern 330. Further, according to one or more other embodiments, the hard mask pattern 330 may be formed such that two or more second portions 330B or none may be formed between any two adjacent first portions 330A among the plurality of first portions 330A.

Referring to FIG. 3D, the initial dummy gate structure 320 may be patterned based on the hard mask pattern 330 to form a plurality of dummy gate structures 340 and dummy support structures 345, as dummy-gate-leaning prevention structures, therebetween to prevent gate-leaning.

Patterning of the initial dummy gate structure 320 in this step may be performed through, for example, dry etching such as reactive ion etching (RIE), not being limited thereto, based on the hard mask pattern 330 to transfer the pattern of the hard mask pattern 330 down to the initial dummy gate structure 320 in the 3^{rd} direction D3. Thus, the dummy gate structures 340 and the dummy support structures 345 respectively corresponding to the 1^{st} portions 330A and the 2^{nd} portions 330B of the hard mask pattern 330 may be obtained. The dummy gate structures 340 and the dummy support structures 345 therebetween may be formed at a same level in the 3^{rd} direction D3 on the substrate 301. For example, at least top surfaces of the dummy gate structures 340 and the dummy support structures 345 may be at a same level in the 3^{rd} direction D3 or horizontally coplanar in the 1^{st} direction D1 or the 2^{nd} direction D2.

In this patterning step and subsequent steps, the dummy gate structures 340 may be subject to gate leaning between two adjacent dummy gate structures 340. However, due to the dummy support structures 345 randomly formed between the two adjacent dummy gate structures 340, formation of the dummy gate structures 340 may avoid the gate-leaning phenomenon to maintain an intended CPP.

Corresponding to the hard mask pattern 330, eight dummy gate structures 340 and eight dummy support structures 345 are formed in the intermediate semiconductor device 30′ as shown in FIG. 3D. However, depending on the pattern of the hard mask pattern 330, more or less than eight dummy gate structures, or more or less than eight dummy support structures may be formed in the intermediate semiconductor device 30′, according to one or more other embodiments. Further, although FIG. 3D shows one or two dummy support structures 345 formed between two adjacent dummy gate structures 340, two or more dummy support structures, or none, may be formed between corresponding two adjacent dummy gate structures 340 depending on the pattern of the hard mask pattern 330, provided that gate leaning can be avoided by the dummy support structures, according to one or more other embodiments.

In this step, a single patterning operation may form the dummy gate structures 340 and the dummy support structures 345 therebetween based on the hard mask pattern 330. As the hard mask pattern 330 is formed of the 1^{st} portions 330A and the 2^{nd} portions 330B which are connected in a single piece or a single continuum structure without a seam, an interface, a connection surface, or a junction therebetween, the dummy gate structures 340 and the dummy support structures 345 may also be connected in a single piece or a single continuum structure without a seam, an interface, a connection surface, or a junction therebetween. Even when no dummy support structure is formed between any two adjacent dummy gate structures 340, other two adjacent dummy gate structures 340 and at least one dummy support structure 345 therebetween may form a single piece or a single continuum structure without a seam, an interface, a connection surface, or a junction therebetween.

In the meantime, when the initial dummy gate structure 320 is patterned based on the hard mask pattern 330 to form the dummy gate structures 340 and the dummy support structures 345, the active patterns 310 below the initial dummy gate structure 320, except portions below the hard mask pattern 330 in the 3^{rd} direction D3, may also be patterned. Thus, these portions of the active patterns 310 may form channel structures 310A, 310B and 310C protruded from the substrate 301 below the dummy gate structures 340 in the 3^{rd} direction D3, as shown by dashed lines in FIG. 3D. At this time, portions of the active patterns 310 below the dummy support structures 345 may also be patterned to form spaces between the substrate 301 and the dummy support structures 345.

These channel structures 310A, 310B and 310C may be surrounded by the dummy gate structures 340. Each of the channel structures 310A, 310B and 310C may be in a form of one or more vertical fin structures for a FinFET or a plurality of nanosheet layers for a nanosheet transistor, not being limited thereto. The patterning operation in this step may expose, in the 3^{rd} direction D3, the top surface of the substrate 301 at sides of the dummy gate structures 340 and the dummy support structures 345.

FIG. 3D does not show the hard mask pattern 330 on the dummy gate structures 340 and dummy support structures 345 because the hard mask pattern 330 may obscure how the dummy gate structures 340 and the dummy support structures 345 are formed below the hard mask pattern 330 and above the substrate 301 in plan view. However, the hard mask pattern 330 may still remain on top surfaces of the dummy gate structures 340 and dummy support structures 345 after the initial dummy gate structure 320 is patterned based on the hard mask pattern 330 to form the dummy gate structures 340 and dummy support structures 345 as shown in FIG. 3E.

Referring to FIG. 3E which illustrates a cross-section view taken along a line I-I′ shown in FIG. 3D, according to one or more embodiments, the hard mask pattern 330 may still remain on the top surface of the dummy gate structures 340 and dummy support structures 345 when the dummy support structure 345 prevents gate leaning between the dummy gate structures 340 at both sides thereof.

Referring to FIG. 3F, source/drain patterns 350 may be formed between the dummy gate structures 340 based on the channel structures 310A, 310B and 310C.

The source/drain patterns 350 may be epitaxially grown from the channel structures 310A, 310B and 310C mainly along the 1^{st} direction D1 to form respective active regions (source/drain regions or patterns) on the substrate 301. The source/drain patterns 350 may be formed of silicon (Si) or silicon germanium (SiGe), and also be in-situ doped with impurities. When two source/drain patterns 350 are to form a transistor of n-type, these two source/drain patterns 350 may be formed of silicon (Si) doped with impurities such as phosphorus (P), arsenic (As), or antimony (Sb). In contrast, when two source/drain patterns 350 are to form a transistor of p-type, these two source/drain patterns 350 may be formed of silicon germanium (SiGe) doped with impurities such as boron (B), gallium (Ga), or indium (In).

After the source/drain patterns 350 are formed in the above manner, the hard mask pattern 330 formed on the dummy gate structures 340 and the dummy support structures 345 may be removed through, for example, ashing, stripping or dry etching, not being limited thereto.

Referring to FIG. 3G, the dummy gate structures 340 with the dummy support structures 345 therebetween may be replaced by a plurality of gate structures 360 (G1-G8) with gate support structures 365 (S1-S8) as gate-leaning prevention structures.

The dummy gate structures 340 and the dummy support structures 345 may be removed through, for example, dry or wet etching followed by deposition, such as CVD or ALD, of a metal or metal alloy in a space generated by the removal of the dummy gate structures 340 and the dummy support structures 345. Thus, the gate structures 360 (G1-G8) with the gate support structures 365 (S1-S8) therebetween corresponding to the dummy gate structures 340 and the dummy support structures 345, respectively, may be formed in the intermediate semiconductor device 30′

As the gate structures 360 and the gate support structures 365 are formed in a single deposition step, the gate structures 360 and the gate support structures 365 may be formed of a same metal or metal alloy which may include tungsten (W), aluminum (Al), copper (Cu), cobalt (Co), molybdenum (Mo), ruthenium (Ru), etc., not being limited thereto. Further, the gate structures 360 and the gate support structures 365 may include the same gate dielectric layer and work-function layer surrounding the channel structures 310A-310C.

Like the dummy gate structures 340 and the dummy support structures 345 therebetween, the gate structures 360 and the gate support structures 365 therebetween may be formed at a same level in the 3^{rd} direction D3 on the substrate 301. For example, top surfaces of the gate structures 360 and the gate support structures 365 may be at a same level in the 3^{rd} direction D3 or horizontally coplanar in the 1^{st} direction D1 or the 2^{nd} direction D2.

Also, like the dummy gate structures 340, the gate structures 360 may also be subject to gate leaning in this step of etching and deposition or subsequent operations. However, due to the gate support structures 365 randomly formed between the gate structures 360, formation of the gate structures 360 may avoid gate leaning to maintain the intended CPP.

As the gate structures 360 and the gate support structures 365 are replacement of the dummy gate structures 340 and the dummy support structures 345, respectively, eight gate structures 360 and eight gate support structures 365 are formed in the intermediate semiconductor device 30′ as shown in FIG. 3F. However, like the dummy gate structures 340 and the dummy support structures 345, more or less than eight gate structures, or more or less than eight gate support structures may be formed in the intermediate semiconductor device 30′, according to one or more other embodiments. Further, although FIG. 3G shows one or two gate support structures 365 formed between two adjacent gate structures 360, two or more gate support structures, or none, may be formed between corresponding two adjacent gate structures 360 depending on the pattern of the dummy support structures 345, provided that gate leaning can be avoided by the gate support structures, according to one or more other embodiments.

In this step, a single deposition operation filling in the space generate by the removal of the dummy gate structures 340 and the dummy support structures 345 therebetween may form the gate structures 360 and the gate support structures 365 in a single connected piece or a single continuum structure without a seam, an interface, a connection surface, or a junction therebetween. Even when no gate support structure is formed between any two adjacent gate structures 360, other two adjacent gate structures 360 and at least one gate support structure 365 therebetween may form a single piece or a single continuum structure without a seam, an interface, a connection surface, or a junction therebetween.

Referring to FIG. 3H, selected gate support structures among the gate support structures 365 (S1-S8) may be removed as necessary to form transistor structures to complete a semiconductor device 30 from the intermediate semiconductor device 30′.

As shown in FIG. 3H, each of the gate support structures S1-S8 is formed between two adjacent gate structures to support the two gate structures and prevent gate leaning therebetween. However, as each of the gate support structures S1-S8 formed of a metal or metal alloy is also a connection structure of the two gate structures, an unnecessary or forbidden electrical connection may be formed between these two gate structures to disrupt formation of a desired circuit structure in the semiconductor device 30. Thus, removal of selected gate support structures may be performed in this step.

Among the gate support structures S1-S8, the gate support structures S3 and S5 may be removed in a gate-cut operation, and the gate support structures S2, S4 and S6 may be removed through a separate patterning operation.

The gate-cut operation divides a gate structure extended in the 2^{nd} direction D2 into two or more gate structures and a gate-cut structure may be formed in a space between the divided gate structures so that each of the divided gate structures can form a corresponding transistor along with a channel structure surrounded by the gate structure and source/drain patterns connected through the channel structure. A position of gate cut on a gate structure may be between two adjacent active regions (source/drain regions) in the 2^{nd} direction D2. For example, as shown in FIG. 3H, gate cut may be performed at a gate-cut position on the gate structure G4 to generate a gate-cut space 380 between two adjacent channel structures 310B and 310C in the 2^{nd} direction D2. In this gate-cut space 380 may be formed a gate-cut structure including an isolation material such as silicon nitride (SiN, Si₃N₄, etc.) in a later step.

Thus, when a circuit structure for a semiconductor device requires gate cut on a certain gate structure, a gate support structure may be formed at a position, between this gate structure and an adjacent gate structure, which is a lateral side of a gate-cut position on the gate structure, so that the gate support structure may support these two gate structures and prevent gate leaning therebetween until removed. Therefore, when the gate-cut operation is performed on the gate structure, the gate support structure at the lateral side thereof may be removed together with a portion of the gate structure at the gate-cut position in a simplified manner.

For example, referring to FIGS. 3G and 3H, when a circuit design requires gate cut at a gate-cut position on the gate structure G4 corresponding to the gate-cut space 380, the gate support structure S3 may be formed at a positon, between the gate structure G4 and the gate structure G3 (or G5), which is a lateral side of the gate-cut position so that the gate support structure S3 can be removed along with a portion of the gate structure G4 at the gate-cut position. Thus, the hard mask pattern 330 shown in FIG. 3C may be formed to have a second portion 330B at a corresponding position so that a dummy support structure 345 of the dummy gate structures 340 can be formed at a corresponding position. Similarly, the gate support structure S5 may also be formed at a position which is a lateral side of a gate-cut position on the gate structure G6 so that the gate support structure S5 can be removed along with a portion of the gate structure G6 at the gate-cut position.

However, the gate support structures may be formed at positions different from the position at a lateral side of a gate-cut position on a gate structure. For example, referring to FIG. 3G, the gate support structures S2, S4 and S6 may be formed randomly in the semiconductor device 30, which may correspond to a semiconductor cell where the semiconductor device 30 is formed. Thus, the hard mask pattern 330 shown in FIG. 3C may be formed to have respective 2^{nd} portions 330B at corresponding positions so that the dummy support structures 345 of the dummy gate structures 340 can be formed at corresponding positions. Like the other gate support structures, the gate support structures S2, S4 and S6 may also be formed to support two adjacent gate structures and prevent gate leaning therebetween. The gate support structure S2 may be formed vertically above a source/drain pattern between the gate structures G2 and G3. The gate support structure S4 may be formed vertically above a side surface of a source/drain pattern between the gate structures G4 and G5, and the gate support structure S6 may be formed vertically above the top surface of the substrate 301 between two adjacent source/drain patterns between the gate structures G6 and G7. Thus, these gate support structures S2, S4 and S6 may be removed though a separate patterning operation.

However, as each of the gate support structures S2, S4 and S6 is connected to side surfaces of two adjacent gate structures facing each other in the 1^{st} direction D1, the patterning operation, e.g., dry etching, to remove the gate support structures S2, S4 and S6 may also remove a portion of each of the side surfaces of the adjacent gate structures as shown in FIG. 3H because of an insufficient process margin allowed for manufacturing a high-density semiconductor device. For example, as shown in FIG. 3H, in a patterned region 370 generated by removing the gate support structure S2, a portion of a right side surface of the gate structure G2 and a portion of a left side surface of the gate structure G3 facing each other may be removed or patterned along with the gate support structure S2 to form respective recesses or dents thereon. In contrast, a left side surface of the gate structure G2 and a right side surface of the gate structure G3 may not be recessed or dented because these side surfaces are free of removal of gate support structures.

Similarly, a patterned region generated by removing each of the gate support structures S4 and S6 may also include partially patterned (e.g., recessed or dented) side surfaces of two adjacent gate structures. Further, as each of the gate support structures S2 and S4 is formed vertically above at least a portion of a corresponding source/drain pattern therebelow, the patterning operation removing the gate support structure S2 and S4 may pattern (e.g., etch) at least a portion of the corresponding source/drain pattern therebelow because of the insufficient process margin. Thus, the removal of the gate support structures S2 and S4 may leave at least a recess or dent on the top surface of the corresponding source/drain pattern in addition to partially patterned side surface of the two adjacent gate structures.

Considering this partial patterning on the side surfaces of the two adjacent gate structures facing each other and/or the top surface of the corresponding source/drain pattern that may occur during the process of removal of the gate support structures, the gate support structures S2 and S4 may be formed at positions above the source/drain patterns which may be disabled or not functional when the semiconductor device 30 is powered on or activated.

The separate patterning operation to remove the gate support structures S2, S4 and S6 may be performed through, for example, dry etching, not being limited thereto, which may also be used for the gate-cut operation. Thus, this separate patterning operation and the gate-cut operation may be performed as a single operation or at a single step to remove the gate support structures S3, S5, S2, S4 and S6 substantially at the same time.

In contrast, the gate support structures S1, S7 and S8 may not be removed to remain between the gate structures G1 and G2 and between the gate structures G7 and G8, respectively. The gate support structure S7 and S8 may remain between the gate structures G7 and G8 because these two gate structures are both a disabled gate structure or a non-operational gate structure when the semiconductor device 30 is powered on or activated, for example, a gate structure which does not receive a gate input signal or is not connected to any circuit element to function as a transistor element. Thus, the gate support structures S7 and S8 connecting the side surfaces of the gate structures G7 and G8 facing each other may not require removal as electrical connection between two gate support structures S7, S8, and the gate structures G7 and G8 do not affect the intended functions of the circuit structure formed in the semiconductor device 30.

The gate support structure S1 may remain between the gate structures G1 and G2 to electrically connect these two gate structures when a common gate input signal is input to these two gate structures which may form a complementary metal-oxide-semiconductor (CMOS) device. In this case, the gate support structure S1 may not only prevent gate leaning between the two gate structures G1 and G2 but also replace one or more via structures and metal lines connecting these two gate structures to receive the common gate input signal. As no via structures and metal lines are formed to connect the two gate structures G1 and G2, the semiconductor device 30 may achieve an increase area gain, reduced contact resistance between the metal structures (gate structures, via structures, metal lines, etc.), and manufacturing simplicity. Alternatively, the gate support structure S1 may also be a disabled gate structure or non-operational gate structure like the gate support structures S7 and S8.

Considering the above-described factors for the circuit structure of the semiconductor device 30 including positions of gate-cut, disabled or non-functional source/drain patterns or gate structures, and gate structures to receive a common gate input signal, the hard mask pattern 330 shown in FIG. 3C may be formed to include respective 2^{nd} portions 330B at corresponding positions so that the dummy support structures 345 of the dummy gate structures 340 can be formed at corresponding positions and replaced by the gate support structures 365 of the gate structures 360, respectively, as shown in FIGS. 3D-3G before the selective removal as shown in FIG. 3H. Thus, at least until the gate-cut operation is finished, the dummy gate structures 340 and the gate structures 360 may avoid gate leaning and the gate structures 360 may be formed to have the intended CPP therebetween. However, the disclosure is not limited thereto, the positions of the 2^{nd} portions 330B of the hard mask pattern 330 may be determined based on only one or two among the above-described factors or different factors as long as gate leaning can be avoided without disrupting intended circuit functions of the semiconductor device 30.

Following embodiments provide a semiconductor device in which gate support structures formed to have a uniform pattern only in a gate-cut position.

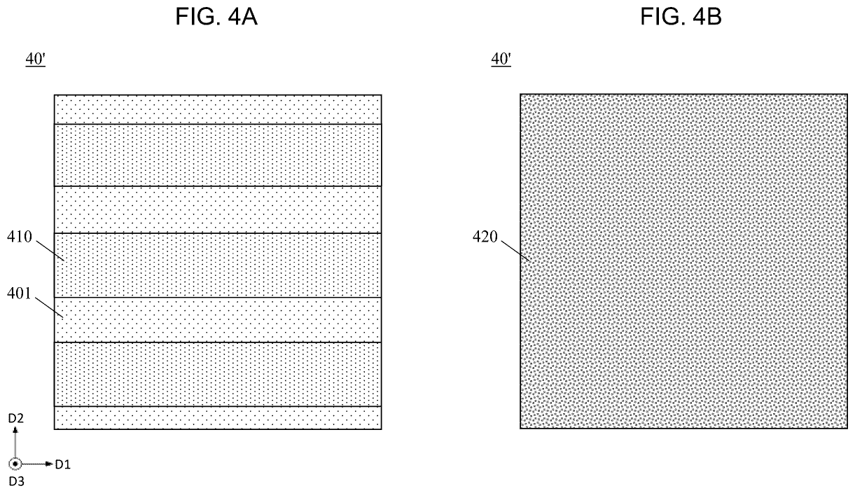

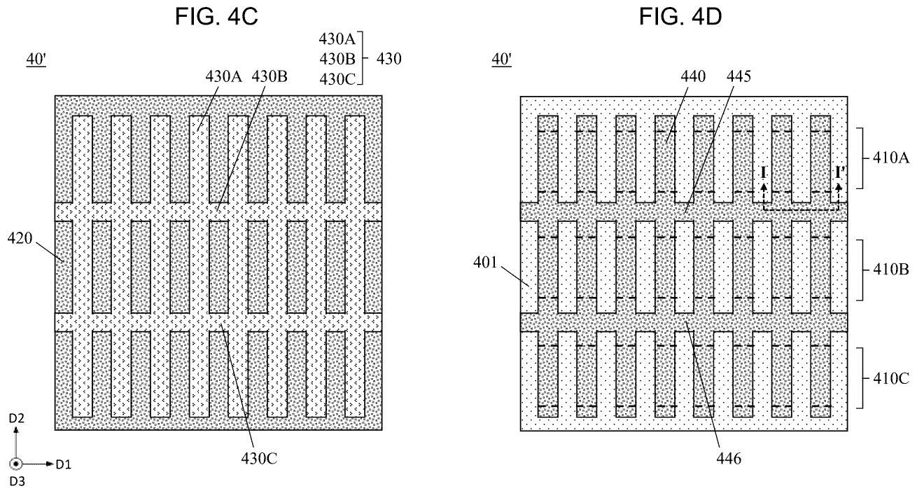

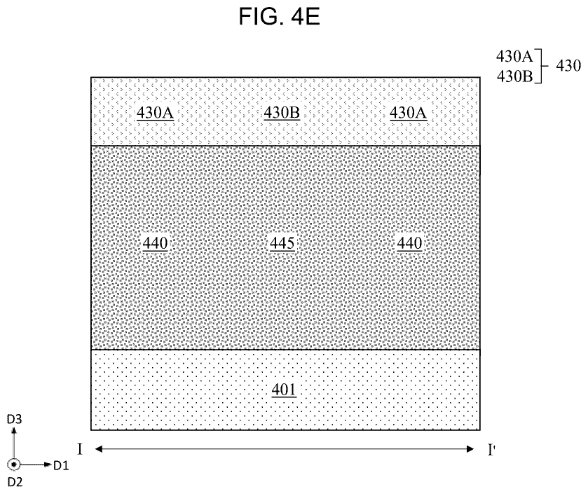

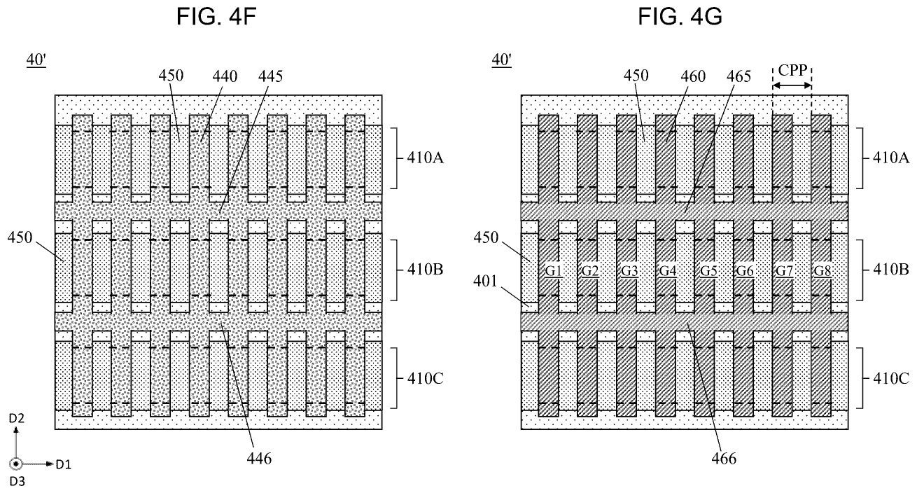

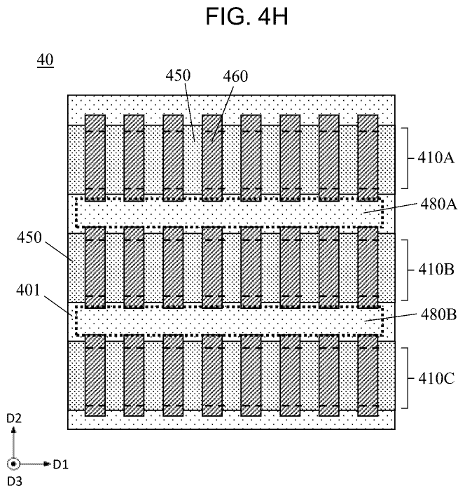

FIGS. 4A-4H illustrate intermediate semiconductor devices obtained after respective steps of manufacturing a semiconductor device using a uniformly-positioned dummy gate support structure as a gate-leaning prevention structure, according to one or more embodiments.

Referring to FIGS. 4A and 4B, an intermediate semiconductor device 40′ including a substrate 401 and a plurality of active patterns 410 formed thereon may be provided and an initial dummy gate structure 420 may be formed on top surfaces of the active patterns 410 and the substrate 401 exposed between the active patterns 410. As the substrate 401, the active patterns 410 and the initial dummy gate structure 420 may be the same structural elements as the substrate 301, the active patterns 310 and the initial dummy gate structures 320 of FIGS. 3A and 3B, duplicate descriptions thereof may be omitted herein.

Referring to FIG. 4C, a hard mask pattern 430 may be formed on a top surface of the initial dummy gate structure 420 to pattern a plurality of dummy gate structures in a next step (FIG. 4D).

The hard mask pattern 430 may be formed through the same process using the same material (e.g., photolithography and dry etching) as the hard mask pattern 330 of the intermediate semiconductor device 30′, and thus, duplicate descriptions thereof may be omitted herein. Like the hard mask pattern 330, the hard mask pattern 430 may also be a multi-layer hard mask pattern including a silicon nitride pattern and a silicon oxide pattern alternatingly stacked in the 3^{rd} direction D3.

The hard mask pattern 430 may include a plurality of 1^{st} portions 430A which have the same pattern (shape or form) or dimensional as the 1^{st} portions 330A of the hard mask pattern 330. However, unlike the hard mask pattern 330 of the intermediate semiconductor device 30′ having the randomly positioned second portions 330B, the hard mask pattern 430 of the intermediate semiconductor device 40′ may have two sets of 2^{nd} portions 430B and 430C which are uniformly arranged in the 1^{st} direction D1 between or across the 1^{st} portions 430A. For example, a 1^{st} set of 2^{nd} portions 430B may be formed at a same 2^{nd}-direction coordinate between the 1^{st} portions 430A at lateral sides of 1^{st} gate-cut positions on a plurality of gate structures to be formed in a later step (FIG. 4H). A 2^{nd} set of 2^{nd} portions 430C may also be formed at another same 2^{nd}-direction coordinate between the 1^{st} portions 430A at lateral sides of 2^{nd} gate-cut positions on the same gate structures. Still, however, as in the hard mask pattern 330 of the intermediate semiconductor device 30′, an “H” shape may be formed by two adjacent 1^{st} portions 430A and a 2^{nd} portion 430B or 430C therebetween connecting respective side surface of the two adjacent 1^{st} portions 430A facing each other.

The 1^{st} portions 430A may be formed to pattern a plurality of dummy gate structures and the 2^{nd} portions 430B may be formed to pattern a plurality of dummy support structures between two adjacent dummy gate structures, in a next step (FIG. 4D).

FIG. 4C shows that the hard mask pattern 430 includes eight 1^{st} portions 430A and two sets of 2^{nd} portions 430B and 430C each set having seven 2^{nd} portions 430B between the 1^{st} portions 430A. However, the disclosure is not limited thereto. According to one or more other embodiments, more or less than eight 1^{st} portions, or more or less than two sets of 2^{nd} portions, each set having a different number, including zero, of 2^{nd} portions other than seven, may form the hard mask pattern 430.

Referring to FIG. 4D, the initial dummy gate structure 420 may be patterned based on the hard mask pattern 430 to form a plurality of dummy gate structures 440 and two sets of dummy support structures 445 and 446, as dummy-gate-leaning prevention structures, therebetween to prevent gate-leaning.

Patterning of the initial dummy gate structure 420 in this step may be performed, through the same process as the patterning of the initial dummy gate structure 320 of the intermediate semiconductor device 30′, to form the dummy gate structures 440 and the two sets of dummy support structures 445 and 446 respectively corresponding to the 1^{st} portions 430A and the two sets of 2^{nd} portions 430B and 430C of the hard mask pattern 430. Thus, the two sets of dummy support structures 445 and 446 may have the same pattern (shape or form) as the two sets of 2^{nd} portions 430B and 430C of the hard mask pattern 430. For example, a 1^{st} set of dummy support structures 445 may be formed at the same 2^{nd}-direction coordinate as that of the 1^{st} set of 2^{nd} portions 430B of the hard mask pattern 430 at lateral sides of the 1^{st} gate-cut positions on a plurality of gate structures to be formed in a later step (FIG. 4H). Further, a 2^{nd} set of dummy support structures 446 may be formed at the same 2^{nd}-direction coordinate as that of the 2^{nd} set of 2^{nd} portions 430C of the hard mask pattern 430 at lateral sides of the 2^{nd} gate-cut positions on the same gate structures.

In this patterning step and subsequent steps, the dummy gate structures 440 may be subject to gate leaning between two adjacent dummy gate structures 440. However, due to the dummy support structures 445 and 446 connecting the dummy gate structures in the 2^{nd} direction, formation of the dummy gate structures 440 may avoid the gate-leaning phenomenon to maintain an intended CPP.

As the two sets of dummy support structures 445 and 446 have respectively the same 2^{nd}-direction coordinates between the dummy gate structures 440, consistent gate support may be achieved in the intermediate semiconductor device 40′ to prevent gate leaning between the dummy gate structures 440, compared to the gate support and gate-leaning prevention in the intermediate semiconductor device 30′.

FIG. 4D shows that, based on the hard mask pattern 430, the intermediate semiconductor device 40′ includes eight dummy gate structures 440 and two sets of dummy support structures 445 and 446, each set having seven dummy support structures between the dummy gate structures 440. However, the disclosure is not limited thereto. According to one or more other embodiments, more or less than eight dummy gate structures, or more or less than two sets of dummy support structures, each set having a different number, including zero, of dummy support structures other than seven, may be formed in the intermediate semiconductor device 40′, depending on the formation of the hard mask pattern 430.

In this step, a single patterning operation may form the dummy gate structures 440 and the dummy support structures 445 and 446 based on the hard mask pattern 430. As the hard mask pattern 430 is formed of the 1^{st} portions 430A and the 2^{nd} portions 430B which are connected in a single piece or a single continuum structure without a seam, an interface, a connection surface, or a junction therebetween, the dummy gate structures 440 and the dummy support structures 445 and 446 may also be connected in a single piece or a single continuum structure without a seam, an interface, a connection surface, or a junction therebetween. Even when no dummy support structure is formed between any two adjacent gate structures 440, other two adjacent dummy gate structures 440 and at least one dummy support structure 445 or 446 therebetween may form a single piece or a single continuum structure without a seam, an interface, a connection surface, or a junction therebetween.

The dummy gate structures 440 and the dummy support structures 445 and 446 therebetween may be formed at a same level in the 3^{rd} direction D3 on the substrate 401. For example, at least top surfaces of the dummy gate structures 440 and the dummy support structures 445 and 446 may be at a same level in the 3^{rd} direction D3 or horizontally coplanar in the 1^{st} direction D1 or the 2^{nd} direction D2.

In the meantime, when the dummy gate structures 440 and the dummy support structures 445 and 446 are patterned from the initial dummy gate structure 420 based on the hard mask pattern 430, the active patterns 410 below the initial dummy gate structure 420 may also be patterned to form channel structures 410A, 410B and 410C below the dummy gate structures 440, as shown by dashed lines in FIG. 4D. These channel structures 410A, 410B and 410C may be surrounded by the dummy gate structures 440. Each of channel structures 410A, 410B and 410C may be in a form of one or more vertical fin structures for a FinFET or a plurality of nanosheet layers for a nanosheet transistor, not being limited thereto. The patterning operation in this step may expose, in the 3^{rd} direction D3, the top surface of the substrate 401 at sides of the dummy gate structures 440 and the dummy support structures 445 and 446.

FIG. 4D does not show the hard mask pattern 430 on the dummy gate structures 440 and dummy support structures 445 and 446 because the hard mask pattern 430 may obscure how the dummy gate structures 440 and the dummy support structures 445 and 446 are formed below the hard mask pattern 430 and above the substrate 401 in plan view. However, the hard mask pattern 430 may still remain on top surfaces of the dummy gate structures 440 and dummy support structures 445 and 446 after the initial dummy gate structure 420 is patterned based on the hard mask pattern 430 to form the dummy gate structures 440 and dummy support structures 445 and 446 as shown in FIG. 4E.

Referring to FIG. 4E which illustrates a cross-section view taken along a line I-I′ shown in FIG. 4D, according to one or more embodiments, the hard mask pattern 430 may still remain on the top surface of the dummy gate structures 440 and dummy support structure when the dummy support structure 445 prevents gate leaning between the dummy gate structures 440 at both sides thereof.

Referring to FIG. 4F, source/drain patterns 450 may be formed between the dummy gate structures 440 based on the channel structures 410A, 410B and 410C.

Formation of the source/drain patterns 450 may be performed in the same manner as the formation of the source/drain patterns 350 in the intermediate semiconductor device 30′, and thus, duplicate descriptions thereof may be omitted herein.

As the source/drain patterns 450 are epitaxially grown from the respective channel structures 410A, 410B and 410C mainly in the 1^{st} direction D1 to form respective active regions (source/drain regions or patterns), the 1^{st} set of the dummy support structures 445 may be positioned between two active regions corresponding to the channel structures 410A and 410B, and the 2^{nd} set of the dummy support structures 446 may be positioned between two active regions corresponding to the channel structures 410B and 410C. As will be described later, these two positions correspond to the two gate-cut positions of the intermediate semiconductor device 40′.

After the source/drain patterns 450 are formed in the above manner, the hard mask pattern 430 formed on the dummy gate structures 440 and the dummy support structures 445 and 446 may be removed through, for example, ashing, stripping or dry etching, not being limited thereto.

Referring to FIG. 4G, the dummy gate structures 440 with the dummy support structures 445 and 446 therebetween may be replaced by a plurality of gate structures 460 (G1-G8) with two sets of gate support structures 465 and 466, as gate-leaning prevention structures.

The dummy gate structures 440 and the dummy support structures 445 and 446 may be removed and replaced by the gate structures 460 and the gate support structures 465 and 466 through the same process and material as in the removal of the dummy gate structures 340 and the dummy support structures 345 and replacement with the gate structures 360 and the gate support structures 365. Thus, duplicate descriptions thereof may be omitted herein.

Like the dummy gate structures 440 and the dummy support structures 445 and 446 therebetween, the gate structures 460 and the gate support structures 465 and 466 therebetween may be formed at a same level in the 3^{rd} direction D3 on the substrate 401. For example, top surfaces of the gate structures 460 and the gate support structures 465 and 466 may be at a same level in the 3^{rd} direction D3 or horizontally coplanar in the 1^{st} direction D1 or the 2^{nd} direction D2.

Also, like the dummy gate structures 440, the gate structures 460 may also be subject to gate leaning in this step of etching and deposition or subsequent operations. However, due to the gate support structures 465 and 466 uniformly formed between the two adjacent gate structures 460, formation of the gate structures 460 may avoid gate leaning to maintain the intended CPP.

As the gate structures 460 and the gate support structures 465 and 466 are replacement of the dummy gate structures 440 and the dummy support structures 445 and 446, respectively, the gate support structures 465, like the dummy support structures 445, may be positioned between the two active regions (source/drain regions or patterns) corresponding to the channel structures 410A and 410B and the gate support structures 466, line the dummy support structures 446, may be positioned between two active regions corresponding to the channel structures 410B and 410C.

As shown in FIG. 4G, the intermediate semiconductor device 40′ includes eight gate structures 460 and two sets of gate support structures 465 and 466, each set having seven gate support structures between the gate structures 460. However, the disclosure is not limited thereto. According to one or more other embodiments, more or less than eight gate structures, or more or less than two sets of gate support structures, each set having a different number, including zero, of gate support structures other than seven, may be formed in the intermediate semiconductor device 40′, depending on the formation of the hard mask pattern 430.

In this step, a single deposition operation filling in a space generate by the removal of the dummy gate structures 440 and the dummy support structures 445 and 446 may form the gate structures 460 and the gate support structures 465 and 466 in a single connected piece or a single continuum structure without a seam, an interface, a connection surface, or a junction therebetween. Even when no gate support structure is formed between any two adjacent gate structures 460, other two adjacent gate structures 460 and at least one gate support structure 465 or 466 therebetween may form a single piece or a single continuum structure without a seam, an interface, a connection surface, or a junction therebetween.

Referring to FIG. 4H, the two sets of gate support structures 465 and 466 may be removed to form transistor structures to complete a semiconductor device 40 from the intermediate semiconductor device 40′.

As shown in FIG. 4H, each of the gate support structures 465 and 466 is formed between two adjacent gate structures 460 to support these two gate structures and prevent gate leaning therebetween. However, as each of the gate support structures 465 and 466 formed of a metal or metal alloy is also a connection structure of the two gate structures, an unnecessary or forbidden electrical connection may be formed between these two gate structures to disrupt formation of a desired circuit structure in the semiconductor device 40. Thus, removal of the gate support structures 465 and 466 may be performed in this step.

Referring back to FIG. 4G, the 1^{st} set of gate support structures 465 may be positioned between two active regions (source/drain regions or patterns), corresponding to the channel structures 410A and 410B, in the 2^{nd} direction D2 and at lateral sides of the 1^{st} gate-cut positions on the gate structures 460 in the 1^{st} direction according to design of a circuit structure of the semiconductor device 40. Further, the 2^{nd} set of gate support structures 466 may be positioned between two active regions (source/drain regions), corresponding to the channel structures 410B and 410C, in the 2^{nd} direction and at lateral sides of the 2^{nd} gate-cut positions on the gate structures 460 in the 1^{st} direction D1 also according to the design of the circuit structure of the semiconductor device 40.

Thus, when a gate-cut operation is performed on the two gate-cut positions in each of the gate structures 460 to form the circuit structure for the semiconductor device 40, the gate support structures 465 and 466 may be removed along with portions of the gate structures 460 at the two gate-cut positions through a single patterning operation, thereby facilitating manufacturing simplicity. As a result, each of the gate structures 460 may be divided into three gate structures by two gate-cut spaces 480A and 480B as shown in FIG. 4H where the gate support structures 465 and 466 are removed. Thus, at least until the gate-cut operation is finished, the dummy gate structures 440 and the gate structures 460 may avoid gate leaning and the gate structures 460 may be formed to have an intended CPP therebetween.

After the gate-cut operation, the gate-cut spaces 480A and 480B may be filled in with a gate-cut structure including an isolation material such as silicon nitride (SiN, Si₃N₄, etc.) in a later step.

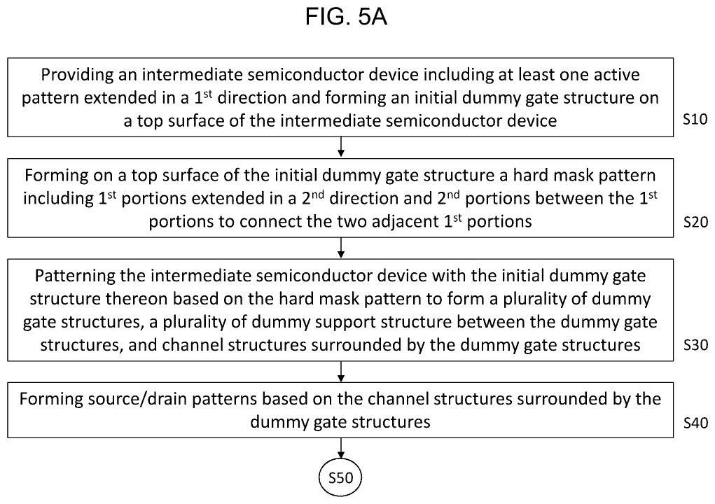

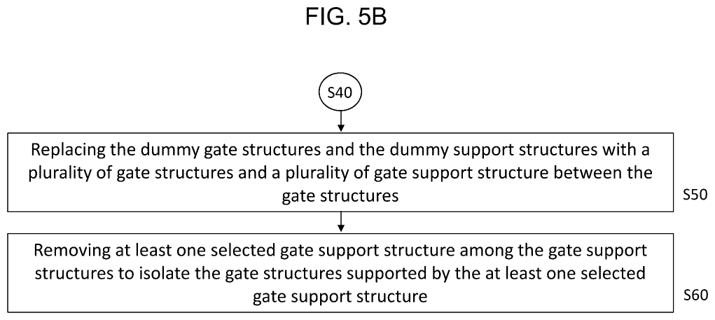

FIGS. 5A and 5B are a flowchart of manufacturing a semiconductor device using a dummy gate support structure as a gate-leaning prevention structure, according to one or more embodiments.

The semiconductor device to be formed through the flowchart of FIGS. 5A and 5B may be the same or similar to the semiconductor device 30 manufactured in reference to FIGS. 3A-3H or the semiconductor device 40 manufactured in reference to FIGS. 4A-4H.

In step S10, an intermediate semiconductor device including at least one active pattern extending in the 1^{st} direction D1 is provided, and an initial dummy gate structure may be formed on a top surface of the intermediate semiconductor device (FIGS. 3A-3B and 4A-4B).

In step S20, on a top surface of the initial dummy gate structure may be formed a hard mask pattern including a plurality of 1^{st} portions extending in the 2^{nd} direction D2 and a plurality of 2^{nd} portions between the 1^{st} portions to connect the two adjacent 1^{st} portions (FIGS. 3C and 4C)

Each of the 2^{nd} portions may be formed between two adjacent 1^{st} portions. The 1^{st} portions may be provided to mask portions of the initial dummy gate structure which are to form a plurality of dummy gate structures, respectively, and the 2^{nd} portions are provided to mask portions of the initial dummy gate structure which are to form a plurality of dummy support structures between the dummy gate structures.

Here, the 2^{nd} portions may be selectively positioned considering where gate cut is to be performed on gate structures to be formed in a later step, which gate structure and/or source/drain pattern are to be disabled or non-functional when a semiconductor device including a plurality of gate structures and source/drain patterns is powered on or activated, and which gate structures can be connected to each other according to a design of a circuit structure of the semiconductor device, etc.

In step S30, the initial dummy gate structure and the active patterns therebelow may be patterned based on the hard mask pattern to form a plurality of dummy gate structures, a plurality of dummy support structure between the dummy gate structures, and channel structures surrounded by the dummy gate structures (FIGS. 3D-3E and 4D-4E).

Corresponding to the hard mask pattern, each of the dummy support structures may be formed between two adjacent dummy gate structures to support these two dummy gate structures to prevent gate leaning that may occur therebetween in this step or subsequent steps.

In step S40, source/drain patterns may be formed based on the channel structures surrounded by the dummy gate structures (FIGS. 3F and 4F).

In step S50, the dummy gate structures and the dummy support structures may be removed and replaced by a plurality of gate structures and a plurality of gate support structure between the gate structures (FIGS. 3G and 4G).

Like the dummy support structures, each of the gate support structures may be formed between two adjacent gate support structures to support these two gate structures to prevent gate leaning that may occur therebetween at least in this step.

In step S60, at least one selected gate support structure among the gate support structures may be removed to isolate the gate structures supported by the at least one selected gate support structure (FIGS. 3H and 4H).

Here, when a gate support structure is formed at a lateral side of a gate-cut position on a gate structure, this gate support structure may be removed together with a portion of the gate structure at the gate-cut position through a gate-cut operation. In addition, another gate support structure may be removed through a separate patterning operation which may be performed at the same time as the gate-cut operation or at different times.

In the above embodiments, a dummy gate support structure is used as a gate-leaning prevention structure in manufacturing a semiconductor device. In the embodiments below, an alternative structural configuration is provided to implement a gate-leaving prevention structure.

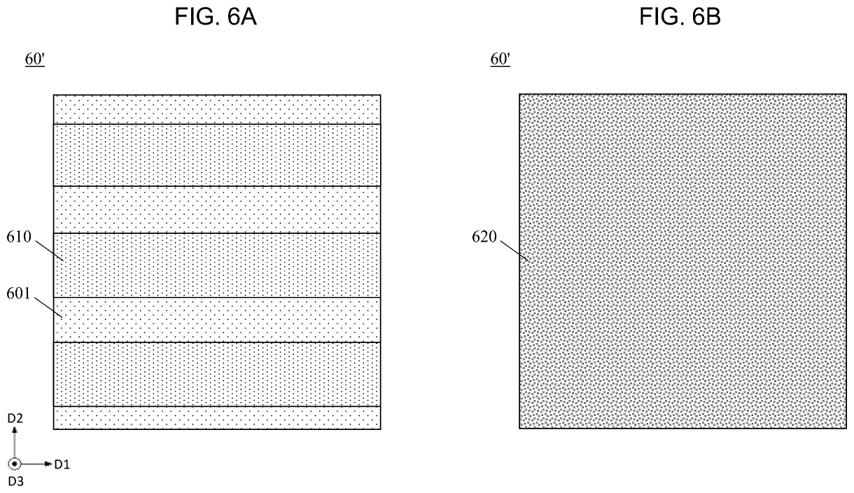

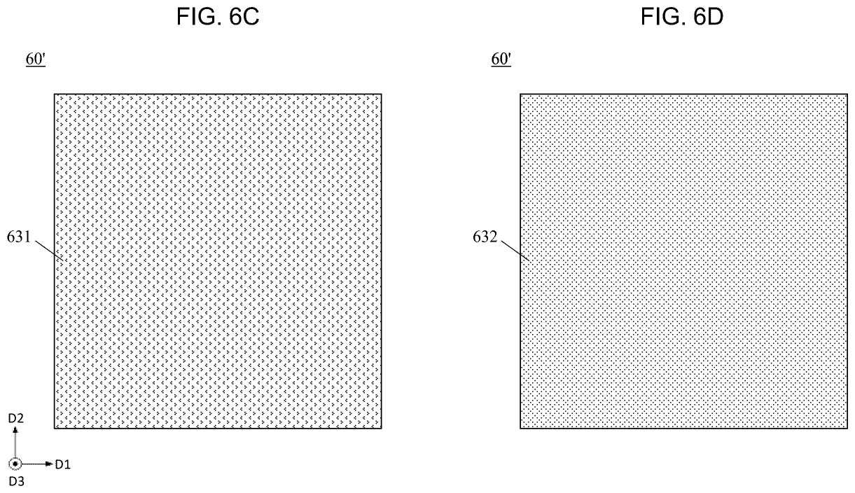

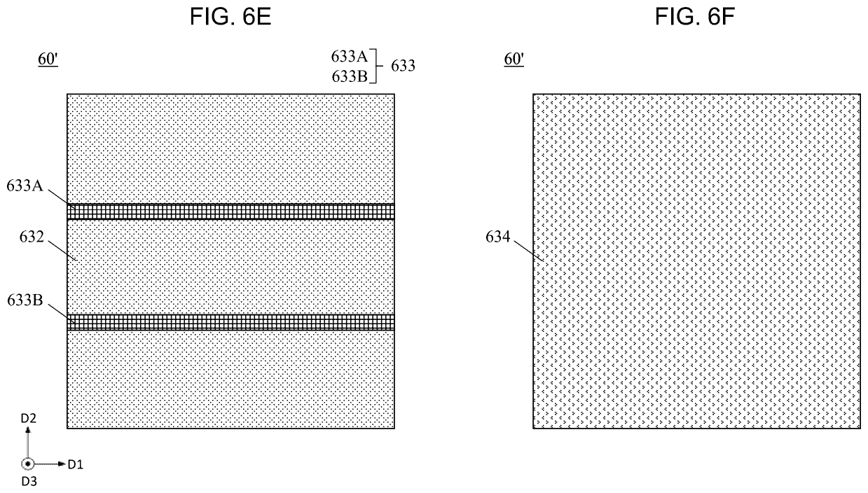

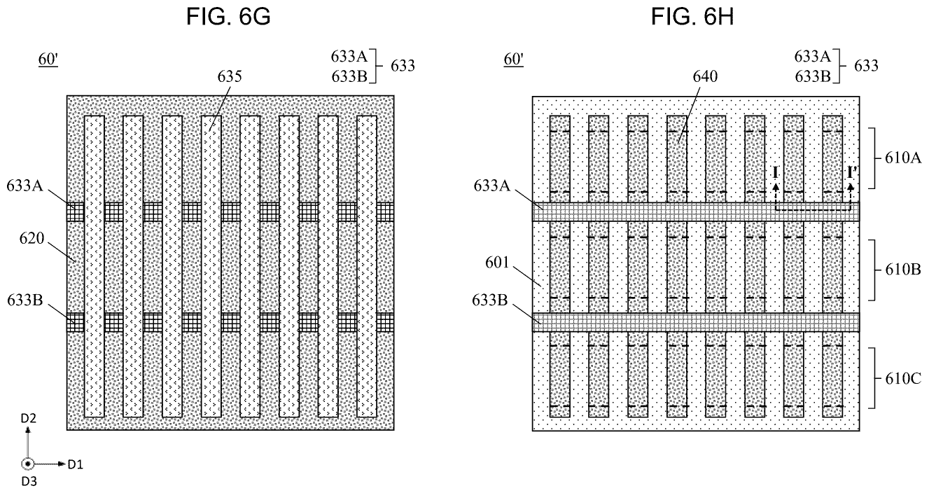

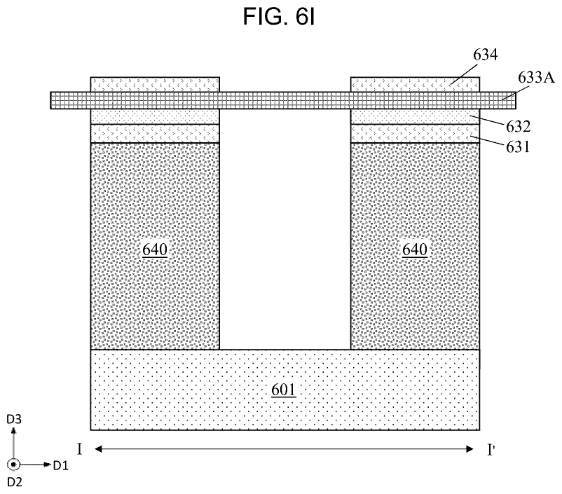

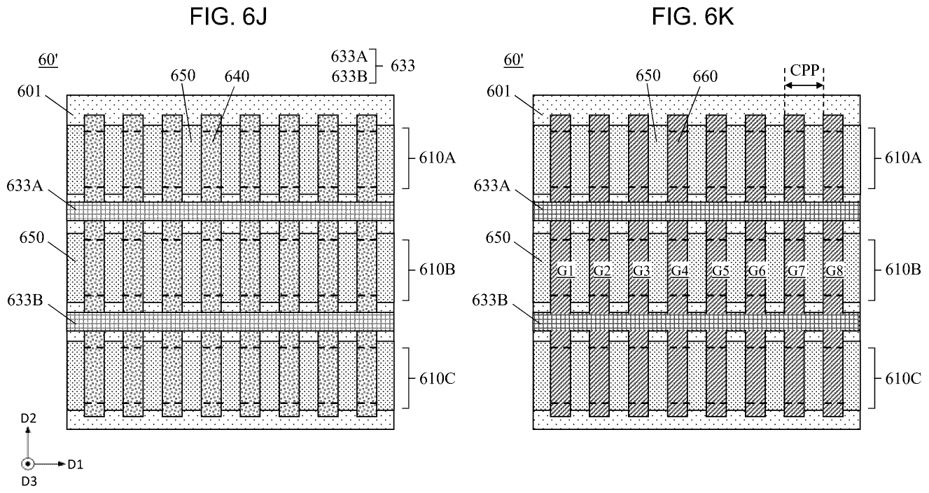

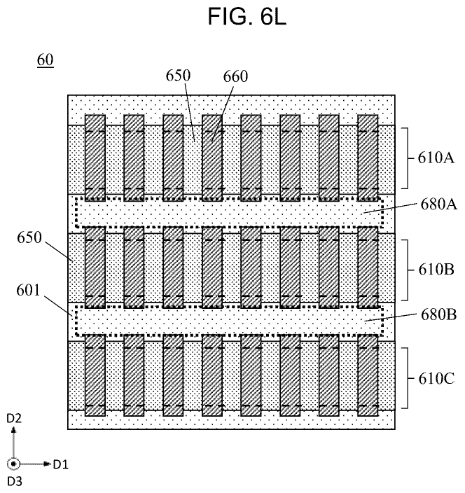

FIGS. 6A-6L illustrate intermediate semiconductor devices obtained after respective steps of manufacturing a semiconductor device using a mask-pattern support structure as a gate-leaning prevention structure, according to one or more embodiments.

Referring to FIGS. 6A and 6B, an intermediate semiconductor device 60′ including a substrate 601 and a plurality of active patterns 610 formed thereon may be provided and an initial dummy gate structure 620 may be formed on top surfaces of the active patterns 610 and the substrate 601 exposed between the active patterns 610. As the substrate 601, the active patterns 610 and the initial dummy gate structure 620 may be the same structural elements as the substrate 301, the active patterns 310 and the initial dummy gate structures 320 of FIGS. 3A and 3B, duplicate descriptions thereof may be omitted herein.

Referring to FIGS. 6C and 6D, a 1^{st} hard mask layer 631 and a 2^{nd} hard mask layer 632 may be formed on a top surface of the initial dummy gate structure 620.

The 1^{st} hard mask layer 631 may be formed by depositing silicon nitride (SiN or Si₃N₄) on the top surface of the initial dummy gate structure 620 through, for example, CVD, PVD, PECVD, not being limited thereto. On the 1^{st} hard mask layer 631 may be formed the 2^{nd} hard mask layer 632 by depositing silicon oxide (e.g., SiO₂) through, for example, CVD, PVD, PECVD, not being limited thereto.

Referring to FIG. 6E, a mask-pattern support structure 633 may be formed on the 2^{nd} hard mask layer 632.

The mask-pattern support structure 633 may include a 1^{st} mask-pattern support structure 633A and a 2^{nd} mask-pattern support structure 633B respectively extending in the 1^{st} direction D1 in parallel. These mask-pattern support structure 633A and 633B may be formed at positions having respective 2^{nd}-directoin coordinates of gate-cut spaces to be formed in a later step (FIG. 6L). These positions of the mask-pattern support structures 633A and 633B may also be between the active patterns 610 along the 2^{nd} direction D2.

Each of the mask-pattern support structures 633A and 633B may be formed on a top surface of the 2^{nd} hard mask layer 632 by depositing a material such as aluminum oxide (e.g., Al₂O₃), titanium nitride (TiN) or silicon carbide (SiC) having etch selectively against silicon nitride and silicon oxide forming the hard mask layers 631 and 632, through, for example, CVD, PVD, PECVD, etc., and patterning this material to form a bar shape extending in the 1^{st} direction D1 through, for example, dry etching, not being limited thereto.

FIG. 6E shows that the mask-pattern support structure 633 includes only two mask-pattern support structures 633A and 633B at the positions of the gate-cut spaces. However, the disclosure is not limited thereto. According to one or more other embodiments, more or less than two mask-pattern support structures may be formed depending on the number of gate structure to be formed through a gate-cut operation in a later step (FIG. 6L).

Referring to FIG. 6F, a 3^{rd} hard mask layer 634 may be formed on the 2^{nd} hard mask layer 632 with the mask-pattern support structure 633 thereon.

The 3^{rd} hard mask layer 634 may be formed by depositing silicon nitride (SiN or Si₃N₄) on a top surface of the 2^{nd} hard mask layer 632 with the mask-pattern support structure 633 thereon through, for example, CVD, PVD, PECVD, not being limited thereto. The 3^{rd} hard mask layer 634 and the 1^{st} hard mask layer 631 may have the same material composition or the 3^{rd} hard mask layer 634 may have a material composition different from that of the 2^{nd} hard mask layer 632.

As the 3^{rd} hard mask layer 634 is formed on the top surface of the 2^{nd} hard mask layer 632 with the mask-pattern support structure 633 thereon, the mask-pattern support structure 633 may be interposed between the 2^{nd} hard mask layer 632 and the 3^{rd} hard mask layer 634 in the 3^{rd} direction D3.

Referring to FIG. 6G, the 1^{st} to 3^{rd} hard mask layers 631, 632 and 634 may be patterned to form a hard mask pattern 635 on a top surface of the initial dummy gate structure 620 with the mask-pattern support structure 633 therein.

The hard mask pattern 635 may be formed to pattern a plurality of dummy gate structures in a next step (FIG. 6H). Thus, the hard mask pattern 635 may have a plurality of patterns extending in the 2^{nd} direction D2 across the active patterns 610 and arranged in the 1^{st} direction D1.

The hard mask pattern 635 may be formed through, for example, applying photolithography and dry etching to the 3^{rd} hard mask layer 634 with the mask-pattern support structure 633, the 2^{nd} hard mask layer 632 and the 1^{st} hard mask layer 631 therebelow. The hard mask pattern 635 may have the same form of the 1^{st} portions 430A of the hard mask pattern 430 of the intermediate semiconductor device 40′ shown in FIG. 4C in plan view. However, unlike the hard mask pattern 430, the hard mask pattern 635 may be formed of four layers, that is, the 1^{st} hard mask layer 631, the 2^{nd} hard mask layer 632, the mask-pattern support structure 633, and the 3^{rd} hard mask layer 634 that are patterned through, for example, photolithography and dry etching.

However, when the stack of the 1^{st} to 3^{rd} hard mask layers 631, 632 and 634 are patterned to form the hard mask pattern 635 through dry etching (or wet etching) using, for example, an etchant such as hydrofluoric acid, the mask-pattern support structure 633 may not be patterned or removed because this etchant may selectively pattern only the 1^{st} to 3^{rd} hard mask layers 631, 632 and 634 formed of silicon nitride and silicon oxide, respectively, without attacking the mask-pattern support structure 633 formed of aluminum oxide, titanium nitride or silicon carbide. Thus, the mask-pattern support structure 633 may survive the patterning operation in this step while the stack of the 1^{st} to 3^{rd} hard mask layers 631, 632 and 634 are patterned as shown in FIG. 6G. At this time, portions of the 1^{st} to 3^{rd} hard mask layers 631, 632 and 634 not forming the hard mask pattern 635 may all be removed. Thus, portion of the 1^{st} hard mask layer 631 and the 2^{nd} hard mask layer 632 vertically below the mask-pattern support structure 633 not overlapped by the hard mask pattern 635 in the 3^{rd} direction D3 may also be removed in the patterning operation in this step.

In the intermediate semiconductor device 40′ shown in FIG. 6G, the mask-pattern support structure 633 may be formed at positions of the 2^{nd} portions 430B of the hard mask pattern 430 of the intermediate semiconductor device 40′ shown in FIG. 4C in plan view.

FIG. 6G shows that the hard mask pattern 635 includes eight patterns extending in the 2^{nd} direction D2 and arranged in the 1^{st} direction D1. However, the disclosure is not limited thereto. According to one or more other embodiments, more or less than eight patterns may form the hard mask pattern 635 depending on a design of a semiconductor device to be formed from the intermediate semiconductor device 60′.

Referring to FIG. 6H, the initial dummy gate structure 620 may be patterned based on the hard mask pattern 635 to form a plurality of dummy gate structures 640 with the mask-pattern support structure 633 thereon as dummy-gate-leaning prevention structures, therebetween to prevent gate-leaning.

Patterning of the initial dummy gate structure 620 in this step may be performed, through the same process as the patterning of the initial dummy gate structure 420 of the intermediate semiconductor device 40′, to form the dummy gate structures 640. At this time, due to the mask-pattern support structure 633, gate leaning between the dummy gate structures 640 may be prevented during the formation thereof, through, for example, dry etching or wet etching.

FIG. 6H shows that, based on the hard mask pattern 635, the intermediate semiconductor device 60′ includes eight dummy gate structures 640. However, the disclosure is not limited thereto. According to one or more other embodiments, more or less than eight dummy gate structures may be formed in the intermediate semiconductor device 60′, depending on the formation of the hard mask pattern 635.

In the meantime, when the dummy gate structures 640 are patterned from the initial dummy gate structure 620 based on the hard mask pattern 635, the active patterns 610 below the initial dummy gate structure 620 may also be patterned to form channel structures 610A, 610B and 610C below the dummy gate structures 640, as shown by dashed lines in FIG. 6H. These channel structures 610A, 610B and 610C may be surrounded by the dummy gate structures 640. Each of channel structures 610A, 610B and 610C may be in a form of one or more vertical fin structures for a FinFET or a plurality of nanosheet layers for a nanosheet transistor, not being limited thereto. The patterning operation in this step may expose, in the 3^{rd} direction D3, the top surface of the substrate 601 at sides of the dummy gate structures 640 and the mask-pattern support structure 633.

In this patterning step and subsequent steps, the dummy gate structures 640 may be subject to gate leaning between two adjacent dummy gate structures 640. However, due to the mask-pattern support structures 633A and 633B interposed between the patterned 2^{nd} hard mask layer 632 and the patterned 3^{rd} hard mask layer 634 in the hard mask pattern 635, formation of the dummy gate structures 640 may avoid the gate-leaning phenomenon to maintain an intended CPP.

FIG. 6H does not show the hard mask pattern 635 on the dummy gate structures 640 and mask-pattern support structure 633 because the hard mask pattern 635 may obscure how the dummy gate structures 640 are formed below the hard mask pattern 635 above the substrate 601 with respect to the mask-pattern support structure 633 in plan view. However, the hard mask pattern 635 shown in FIG. 6G may still remain on top surfaces of the dummy gate structures 640 after the initial dummy gate structure 620 is patterned based on the hard mask pattern 635 to form the dummy gate structures 640 as shown in FIG. 6I.

Referring to FIG. 6I which illustrates a cross-section view taken along a line I-I′ shown in FIG. 6H, according to one or more embodiments, the hard mask pattern 635 may still remain on the top surface of the dummy gate structures 640, and the 1^{st} mask-pattern support structure 633A may be interposed between the patterned 2^{nd} hard mask layer 632 and the patterned 3^{rd} hard mask layer 634 forming the hard mask pattern 635 along with the patterned 1^{st} hard mask layer 631. Thus, the 1^{st} mask-pattern support structure 633A may connect two patterns of the hard mask pattern 635 each of which is formed of the patterned 1^{st} to 3^{rd} hard mask layers 631, 632 and 634 in the 1^{st} direction D1. Accordingly, the 1^{st} mask-pattern support structure 633A supported by the hard mask pattern 635 may prevent gate leaning between the dummy gate structures 640 formed below and connected to the two patterns of the hard mask pattern 635.

Referring to FIG. 6J, source/drain patterns 650 may be formed between the dummy gate structures 640 based on the channel structures 610A, 610B and 610C.

Formation of the source/drain patterns 650 may be performed in the same manner as the formation of the source/drain patterns 450 in the intermediate semiconductor device 40′, and thus, duplicate descriptions thereof may be omitted herein.

As the source/drain patterns 650 are epitaxially grown from the respective channel structures 610A, 610B and 610C mainly in the 1^{st} direction D1 to form respective active regions (source/drain regions or patterns), the 1^{st} mask-pattern support structure 633A may be positioned between two active regions corresponding to the channel structures 610A and 610B, and the 2^{nd} mask-pattern support structure 633B may be positioned between two active regions corresponding to the channel structures 610B and 610C. As will be described later, these two positions correspond to the two gate-cut positions of the intermediate semiconductor device 60′.

After the source/drain patterns 650 are formed in the above manner, the hard mask pattern 635 formed on the dummy gate structures 640, except portions overlapping or overlapped by the mask-pattern support structure 633 along the 3^{rd} direction D3 may be removed through, for example, ashing, stripping or dry etching, not being limited thereto. These portions of the hard mask pattern 635 may include the patterned 1^{st} and 2^{nd} hard mask layers 631 and 632 vertically below the mask-pattern support structure 633 and the patterned 3^{rd} hard mask layer 634 above the mask-pattern support structure 633 which remain to support the mask-pattern support structure 633 through subsequent operations to form gate structures based on the dummy gate structures 640.

Referring to FIG. 6K, the dummy gate structures 640 may be replaced by a plurality of gate structures 660 (G1-G8) based on the mask-pattern support structure 633 as a gate-leaning prevention structure.

The dummy gate structures 640 may be removed and replaced by the gate structures 660 through the same process and material as in the removal of the dummy gate structures 440 and replacement with the gate structures 460. Thus, duplicate descriptions thereof may be omitted herein. At this time, however, the patterned 1^{st} and 2^{nd} hard mask layers 631 and 632 and the patterned 3^{rd} hard mask layer 634 may still remain below and above the mask-pattern support structure 633 in the 3^{rd} direction D3 as shown in FIG. 6I to support the mask-pattern support structure 633.

Thus, while the gate structures 660 is subject to gate leaning in this step of etching and deposition or subsequent operations, the mask-pattern support structure 633 may support the gate structures 660 replacing the dummy gate structures 640 to prevent gate leaning to maintain the intended CPP of the gate structures 660.

As shown in FIG. 6K, the intermediate semiconductor device 60′ includes eight gate structures 660. However, the disclosure is not limited thereto. According to one or more other embodiments, more or less than eight gate structures may be formed in the intermediate semiconductor device 60′, depending on the formation of the hard mask pattern 635.

Referring to FIG. 6L, the mask-pattern support structure 633 may be removed to form transistor structures to complete a semiconductor device 60 from the intermediate semiconductor device 60′.

Referring back to FIG. 6E, the mask-pattern support structure 633 including the 1^{st} mask-pattern support structure 633A and the 2^{nd} mask-pattern support structure 633B may be positioned between two active regions (source/drain regions or patterns), corresponding to the channel structures 610A, 610B and 610C, along the 2^{nd} direction D2. Further, the positions of the mask-pattern support structures 633A and 633B may correspond to gate-cut positions in each of the gate structures 660 to form a circuit structure for the semiconductor device 60. Thus, the mask-pattern support structures 633A and 633B may be removed along with portions of the gate structures 660 at the gate-cut positions through a single patterning operation, thereby facilitating manufacturing simplicity. As a result, each of the gate structures 660 may be divided into three gate structures by two gate-cut spaces 680A and 680B as shown in FIG. 6L. Thus, at least until the gate-cut operation is finished, the dummy gate structures 640 and the gate structures 660 may avoid gate leaning and the gate structures 660 may be formed to have an intended CPP therebetween.

When the mask-pattern support structure 633 is removed, the remaining portions of the hard mask pattern 635 overlapped or overlapping the mask-pattern support structure 633 along the 3^{rd} direction D3 to support the mask-pattern support structure 633 may also be removed.

In the above embodiment, the mask-pattern support structure 633 used as gate-leaning prevention structure is formed between the 2^{nd} hard mask layer 632 and the 3^{rd} hard mask layer 634 among the three hard mask layers 631, 632 and 634. However, the disclosure is not limited thereto. According to one or more other embodiments, more or less than three hard mask layers may be formed to form a hard mask pattern used to form the dummy gate structures 640, and the mask-pattern support structure 633 may be formed any two adjacent hard mask layers to prevent gate-leaning that may occur in the formation of the dummy gate structures 640 and the gate structures 660.

Further, in the above embodiments, the 1^{st} hard mask layer 631 and the 3^{rd} hard mask layer 634 may be formed of silicon nitride and the 2^{nd} hard mask layer 632 may be formed of silicon oxide. However, the disclosure is not limited thereto, and each of these hard mask layers may be formed of a different material with sufficient etch selectively against the mask-pattern support structure 633.

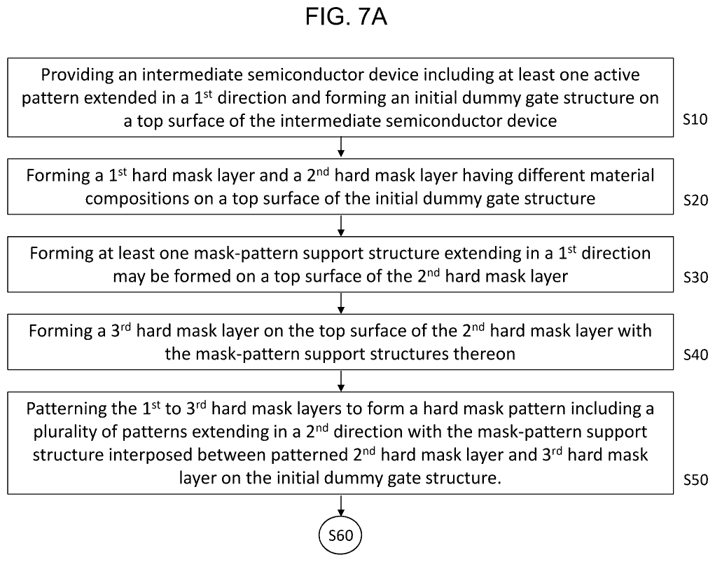

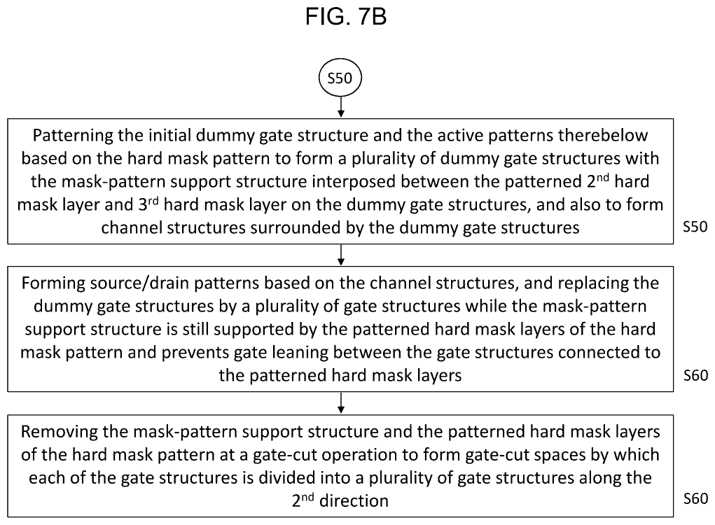

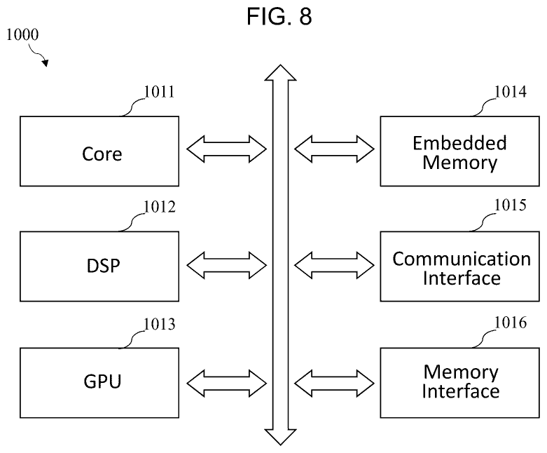

FIGS. 7A and 7B are a flowchart of manufacturing a semiconductor device using a mask-pattern support structure as a gate-leaning prevention structure, according to one or more embodiments.

The semiconductor device to be formed through the flowchart of FIGS. 7A and 7B may be the same or similar to the semiconductor device 60 manufactured in reference to FIGS. 6A-6L.

In step S10, an intermediate semiconductor device including at least one active pattern extending in the 1^{st} direction D1 is provided, and an initial dummy gate structure may be formed on a top surface of the intermediate semiconductor device (FIGS. 6A and 6B).

In step S20, a 1^{st} hard mask layer and a 2^{nd} hard mask layer having different material compositions may be formed on a top surface of the initial dummy gate structure. For example, the 1^{st} hard mask layer may be formed of silicon nitride while the 2^{nd} hard mask layer is formed of silicon oxide.

In step S30, at least one mask-pattern support structure extending in the 1^{st} direction D1 may be formed on a top surface of the 2^{nd} hard mask layer. The mask-pattern support structure may be formed at a position where a gate-cut space is formed in a later step where a gate-cup operation is performed. The mask-pattern support structure may be formed of a material such as aluminum oxide, titanium nitride or silicon carbide having etch selectively against silicon nitride and silicon oxide forming the 1^{st} and 2^{nd} hard mask layers.

In step S40, a 3^{rd} hard mask layer may be formed on the top surface of the 2^{nd} hard mask layer with the mask-pattern support structures thereon. The 3^{rd} hard mask layer may be formed of silicon nitride forming the 1^{st} hard mask layer.

In step S50, the 1^{st} to 3^{rd} hard mask layers may be patterned to form a hard mask pattern including a plurality of patterns extending in the 2^{nd} direction D2 may be formed with the mask-pattern support structure interposed between a patterned 2^{nd} hard mask layer and a patterned 3^{rd} hard mask layer on the initial dummy gate structure. Due to the etch selectivity of the mask-pattern support structure against the three hard mask layers, the mask-pattern support structure may not be patterned to remain between the patterned 2^{nd} hard mask layer and the patterned 3^{rd} hard mask layer and connect the plurality of patterns in the 1^{st} direction D1.

In step S60, the initial dummy gate structure and the active patterns therebelow may be patterned based on the hard mask pattern to form a plurality of dummy gate structures with the mask-pattern support structure interposed between the patterned 2^{nd} hard mask layer and the patterned 3^{rd} hard mask layer on the dummy gate structures, and also to form channel structures surrounded by the dummy gate structures.

At this time, the mask-pattern support structure interposed between the patterned two hard mask layers of the hard mask pattern may prevent gate leaning between the dummy gate structures arranged in the 1^{st} direction D1, extending in the 2^{nd} direction D2 and connected to the patterned hard mask layers of the hard mask pattern.

In step S70, source/drain patterns may be formed based on the channel structures surrounded by the dummy gate structures, and the dummy gate structures may be removed and replaced by a plurality of gate structures while the mask-pattern support structure is still supported by the patterned hard mask layers of the hard mask pattern and prevents gate leaning between the gate structures arranged in the 1^{st} direction D1, extending in the 2^{nd} direction D2 and connected to the patterned hard mask layers of the hard mask pattern.

In step S80, the mask-pattern support structure and the patterned hard mask layers of the hard mask pattern may be removed at a gate-cut operation to form gate-cut spaces by which each of the gate structures is divided into a plurality of gate structures along the 2^{nd} direction D2.

FIG. 8 is a schematic block diagram illustrating an electronic device including one or more semiconductor devices formed using a gate-leaning prevention structure, according to one or more embodiments. The semiconductor devices of the electronic device may include one or more of the semiconductor devices shown in FIGS. 3G, 4G and 6L according to one or more embodiments.

Referring to FIG. 8, a system-on-chip (SoC) 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include one or more of the semiconductor devices shown in FIGS. 3G, 4G and 6L, according to one or more embodiments.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A semiconductor device comprising:
a 1^{st} gate structure;
a 2^{nd} gate structure adjacent to the 1^{st} gate structure in a 1^{st} direction; and
a gate support structure between the 1^{st} gate structure and the 2^{nd} gate structure, the gate support structure connecting the 1^{st} gate structure and the 2^{nd} gate structure.

2. The semiconductor device of claim 1, wherein the gate support structure, the 1^{st} gate structure and the 2^{nd} gate structure are a single piece structure without a seam, connection surface, interface or junction therebetween.

3. The semiconductor device of claim 2, wherein the gate support structure, the 1^{st} gate structure and the 2^{nd} gate structure comprise a same material composition.

4. The semiconductor device of claim 1, wherein the gate support structure, the 1^{st} gate structure and the 2^{nd} gate structure comprise a same material composition.

5. The semiconductor device of claim 1, wherein the gate support structure, the 1^{st} gate structure and the 2^{nd} gate structure are at a same level in a vertical direction.

6. The semiconductor device of claim 1, wherein a side surface of the 2^{nd} gate structure comprises a recessed portion.

7. The semiconductor device of claim 1, wherein further comprising a 3^{rd} gate structure at a side of the 2^{nd} gate structure at a same level as the 1^{st} gate structure and the 2^{nd} gate structure,
wherein a side surface of the 3^{rd} gate structure facing the side surface of the 2^{nd} gate structure comprises a recessed portion.

8. The semiconductor device of claim 7, wherein the 3^{rd} gate structure faces a 4^{th} gate structure with a gate-cut space therebetween,
wherein the 3^{rd} gate structure is at a same level as the 4^{th} gate structure.

9. The semiconductor device of claim 1, wherein the 1^{st} gate structure and the 2^{nd} gate structure is configured to receive a common gate input signal.

10. The semiconductor device of clam 1, wherein the 1^{st} gate structure and the 2^{nd} gate structure are non-functional or disabled when the semiconductor device is activated or powered on.

11. A semiconductor device comprising:
a source/drain pattern and a channel structure connected in a 1^{st} direction; and
a 1^{st} gate structure extending in a 2^{nd} direction across the channel structure, the 2^{nd} direction intersecting the 1^{st} direction,
wherein a side surface of the 1^{st} gate structure comprises a 1^{st} recessed portion.

12. The semiconductor device of claim 11, further comprising a 2^{nd} gate structure extending in the 2^{nd} direction and adjacent to the 1^{st} gate structure in the 1^{st} direction,
wherein a side surface of the 2^{nd} gate structure facing the side surface of the 1^{st} gate structure comprises a 2^{nd} recessed portion facing the 1^{st} recessed portion in the 1^{st} direction.

13. The semiconductor device of claim 12, wherein the 1^{st} gate structure and the 2^{nd} gate structure are at a same level in a 3^{rd} direction intersecting the 1^{st} direction and the 2^{nd} direction.

14. The semiconductor device of claim 11, wherein an opposite side surface of the 1^{st} gate structure is not recessed.

15. The semiconductor device of claim 11, wherein a region at a lateral side of the 1^{st} recessed portion is vertically above the source/drain pattern in a 3^{rd} direction intersecting the 1^{st} direction and the 2^{nd} direction.

16. A method of manufacturing a semiconductor device, the method comprising:
forming a 1^{st} gate structure and a 2^{nd} gate structure adjacent to the 1^{st} gate structure, the 1^{st} gate structure and the 2^{nd} gate structure extending in a 2^{nd} direction intersecting a 1^{st} direction; and
forming a gate support structure between the 1^{st} gate structure and the 2^{nd} gate structure to connect the 1^{st} gate structure and the 2^{nd} gate structure.

17. The method of claim 16, wherein the gate support structure, the 1^{st} gate structure and the 2^{nd} gate structure are formed as a single piece structure without a seam, connection surface, interface or junction therebetween.

18. The method of claim 16, wherein the gate support structure, the 1^{st} gate structure and the 2^{nd} gate structure comprise a same metal composition.

19. The method of claim 16, wherein the gate support structure, the 1^{st} gate structure and the 2^{nd} gate structure are at a same level in a vertical direction.

20. The method of claim 16, wherein the 1^{st} gate structure and the 2^{nd} gate structure are non-functional or disabled when the semiconductor device is activated or powered on.

21. A method of manufacturing a semiconductor device, the method comprising:
forming a plurality of dummy gate structures arranged in a 1^{st} direction and extending in a 2^{nd} direction intersecting the 1^{st} direction;
forming a 1^{st} dummy support structure connecting a 1^{st} dummy gate structure and a 2^{nd} dummy gate structure adjacent to the 1^{st} dummy gate structure, among the plurality of dummy gate structures; and
forming a plurality of gate structures and a 1^{st} gate support structure replacing the plurality of dummy gate structures and the 1^{st} dummy support structure,
wherein the 1^{st} gate support structure connects a 1^{st} gate structure and a 2^{nd} gate structure, among the plurality of gate structures, replacing the 1^{st} dummy gate structure and the 2^{nd} dummy gate structure.

22. The method of claim 21, further comprising removing the 1^{st} dummy support structure.

23. The method of claim 21, further comprising performing a gate-cut operation to divide at least one gate structure, among the plurality of gate structures, along the 2^{nd} direction,
wherein the 1^{st} gate support structure remains to connect the 1^{st} gate structure and the 2^{nd} gate structure after the gate-cut operation.

24. The method of claim 21, further comprising performing a gate-cut operation to divide at least one of the 1^{st} gate structure and the 2^{nd} gate structure along the 2^{nd} direction,
wherein the 1^{st} gate support structure is at a side of a gate-cut position where the at least one of the 1^{st} gate structure and the 2^{nd} gate structure is divided, and removed by the gate-cut operation.

25. The method of claim 21, wherein the 1^{st} gate structure, the 2^{nd} gate structure, and the 1^{st} gate support structure are a single piece structure without a seam, connection surface, interface or junction therebetween.

26. A method of manufacturing a semiconductor device, the method comprising:
forming an initial dummy gate structure on a substrate with an active pattern thereon;
forming a 1^{st} hard mask layer on the initial dummy gate structure;
forming a mask-pattern support structure extending in a 1^{st} direction on the 1^{st} hard mask layer;
forming a 2^{nd} hard mask layer on the 1^{st} hard mask layer with the mask-pattern support structure thereon;
patterning the 1^{st} hard mask layer and the 2^{nd} hard mask layer to form a hard mask pattern comprising a plurality of patterns arranged in the 1^{st} direction and extending in a 2^{nd} direction intersecting the 1^{st} direction;
patterning the initial dummy gate structure based on the hard mask pattern to form a plurality of dummy gate structures arranged in the 1^{st} direction and extending in the 2^{nd} direction;
forming a plurality of gate structures replacing the plurality of dummy gate structures; and
removing the mask-pattern support structure.

27. The method of claim 26, wherein the 1^{st} hard mask layer and the 2^{nd} hard mask layer comprise a material composition having etch selectively against a material composition of the mask-pattern support structure.

28. The method of claim 26, wherein the 1^{st} hard mask layer comprises silicon nitride, and the 2^{nd} hard mask layer comprises silicon oxide.

29. The method of claim 26, further comprising performing a gate-cut operation to divide at least one of the plurality of gate structures along the 2^{nd} direction,
wherein the mask-pattern support structure is removed though the gate-cut operation.

30. The method of claim 26, further comprising further comprising performing a gate-cut operation to divide at least one of the plurality of gate structures along the 2^{nd} direction,
wherein the mask-pattern support structure is on a gate-cut position where at least one of the plurality of gate structures is divided.
